(19) United States
(12) Patent Application Publication
(10) Pub. No.: US 2011/0091006 A1
(43) Pub. Date: Apr. 21, 2011

(54) SHIFT REGISTER CIRCUIT

(76) Inventors: Chin-Wei Liu, Hsin-Chu (TW); Wei-Hsien Wu, Hsin-Chu (TW); Jing-Ru Chen, Hsin-Chu (TW)

(21) Appl. No.: 12/753,097

(22) Filed: Apr. 1, 2010

(30) Foreign Application Priority Data
Oct. 15, 2009 (TW) 098134945

(51) Int. Cl. G11C 19/00

(52) U.S. Cl. 377/68

(57) ABSTRACT

A shift register circuit includes plural shift register stages for providing plural gate signals to plural gate lines. Each shift register stage includes a pull-up unit, an input unit for receiving an input signal, an energy-store unit for providing a driving control voltage in response to the input signal, a discharging unit, a couple unit and a pull-down unit. The pull-up unit pulls up a first gate signal in response to the driving control voltage. The discharging unit performs a discharging operation for pulling down the driving control voltage. The couple unit is utilized for coupling the energy-store unit with a succeeding shift register circuit stage so that the falling edge of a second gate signal generated by the succeeding shift register stage is capable of shifting down the driving control voltage. The pull-down unit pulls down the first gate signal in response to the second gate signal.

### BACKGROUND OF THE INVENTION

1. Field of the Invention

The present invention relates to a shift register circuit, and more particularly, to a shift register circuit capable of reducing current leakage and mitigating voltage stress.

2. Description of the Prior Art

Along with the advantages of thin appearance, low power consumption, and low radiation, liquid crystal displays (LCDs) have been widely applied in various electronic products for panel displaying. The operation of a liquid crystal display is featured by varying voltage drops between opposite sides of a liquid crystal layer for twisting the angles of the liquid crystal molecules in the liquid crystal layer so that the transmittance of the liquid crystal layer can be controlled for illustrating images with the aid of light source provided by a backlight module. In general, the liquid crystal display comprises plural pixel units, a shift register circuit, and a source driver. The source driver is utilized for providing plural data signals to be written into the pixel units. The shift register circuit comprises a plurality of shift register stages which are employed to generate plural gate signals for controlling the operations of writing the data signals into the pixel units. That is, the shift register circuit is a crucial device for providing a control of writing the data signals into the pixel units.

FIG. 1 is a schematic diagram showing a prior-art shift register circuit 100. As shown in FIG. 1, the shift register circuit 100 comprises a plurality of shift register stages and, for ease of explanation, illustrates an (N−1)th shift register stage 111, an Nth shift register stage 112 and an (N+1)th shift register stage 113. Each shift register stage is employed to generate one corresponding gate signal furnished to one corresponding gate line based on a first clock CK1 and a second clock CK2 having a phase opposite to the first clock CK1. For instance, the (N−1)th shift register stage 111 is employed to generate a gate signal SGn−1 furnished to a gate line GLn−1, the Nth shift register stage 112 is employed to generate a gate signal SGn furnished to a gate line GLn, and the (N+1)th shift register stage 113 is employed to generate a gate signal SGn+1 furnished to a gate line GLn+1. The Nth shift register stage 112 comprises a pull-up unit 120, an input unit 130, an energy-store unit 125, a discharging unit 140, a pull-down unit 150, and a control unit 160. The pull-up unit 120 pulls up the gate signal SGn in response to a driving control voltage VQn. The discharging unit 140 and the pull-down unit 150 are employed to pull down the driving control voltage VQn and the gate signal SGn respectively in response to a pull-down control voltage Vdn generated by the control unit 160.

FIG. 2 is a schematic diagram showing related signal waveforms regarding the operation of the shift register circuit 100 in FIG. 1, having time along the abscissa. The signal waveforms in FIG. 2, from top to bottom, are the first clock CK1, the second clock CK2, the gate signal SGn−1, the gate signal SGn, the gate signal SGn+1, the driving control voltage VQn, and the pull-down control voltage Vdn. As shown in FIG. 2, when the driving control voltage VQn is not pulled up to a first high voltage Vh1 or a second high voltage Vh2, the rising and falling edges of the first clock CK1 are able to incur the ripple of the driving control voltage VQn via a capacitive coupling effect caused by the device capacitor of the pull-up unit 120. The ripple of the driving control voltage VQn is an alternating signal which oscillates between a crest voltage Vrc1 and a trough voltage Vrt1. It is noted that the crest voltage Vrc1 is greater than a low power voltage Vss. And therefore the crest voltage Vrc1 may shift to approximate zero voltage due to device aging, temperature variation or other operational factors, which is likely to result in a current leakage event occurring to the pull-up unit 120. In turn, the voltage level of the gate signal SGn will drift significantly and the image quality of the liquid crystal display is degraded accordingly. In another aspect, when the driving control voltage VQn is not pulled up to the first high voltage Vh1 or the second high voltage Vh2, the pull-down control voltage Vdn is retained to around a high power voltage Vdd so as to continue turning on the transistors of the discharging unit 140 and the pull-down unit 150 for continuously pulling down the driving control voltage VQn and the gate signal SGn. That is, the transistors of the discharging unit 140 and the pull-down unit 150 suffer high voltage stress in most of operating time, which is likely to incur an occurrence of threshold voltage shift and degrades the reliability and life-time of the shift register circuit 100.

### SUMMARY OF THE INVENTION

In accordance with an embodiment of the present invention, a shift register circuit is provided for providing plural gate signals to plural gate lines. The shift register circuit comprises a plurality of shift register stages. And an Nth shift register stage of the shift register stages comprises a pull-up unit, an input unit, an energy-store unit, a discharging unit, a couple unit, a first pull-down unit, a second pull-down unit, and a control unit.

The pull-up unit, electrically connected to an Nth gate line of the gate lines, is utilized for pulling up an Nth gate signal of the gate signals in response to a driving control voltage and a first clock. The input unit, electrically connected to the pull-up unit and an (N−1)th shift register stage of the shift register stages, is utilized for inputting a first input signal to become the driving control voltage. The first input signal is an (N−1)th gate signal or an (N−1)th start pulse signal generated by the (N−1)th shift register stage. The energy-store unit, electrically connected to the pull-up unit and the input unit, is employed to perform a charging process based on the first input signal. The discharging unit, electrically connected to the energy-store unit and an (N+1)th shift register stage of the shift register stages, is put in use for pulling down the driving control voltage through performing a discharging process in response to an (N+1)th gate signal of the gate signals. The couple unit, electrically connected to the energy-store unit and the (N+1)th shift register stage, is utilized for pulling down the driving control voltage in response to the falling edge of the (N+1)th gate signal. The first pull-down unit, electrically connected to the Nth gate line and the (N+1)th shift register stage, is used for pulling down the Nth gate signal in response to the (N+1)th gate signal. The second pull-down unit, electrically connected to the Nth gate line, is used for pulling down the Nth gate signal in response to a pull-down control voltage. The control unit, electrically connected to the second pull-down unit, is employed to generate the pull-down control voltage in response to a second input signal. The second input signal is a dc voltage or a second clock having a phase opposite to the first clock.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a prior-art shift register circuit.

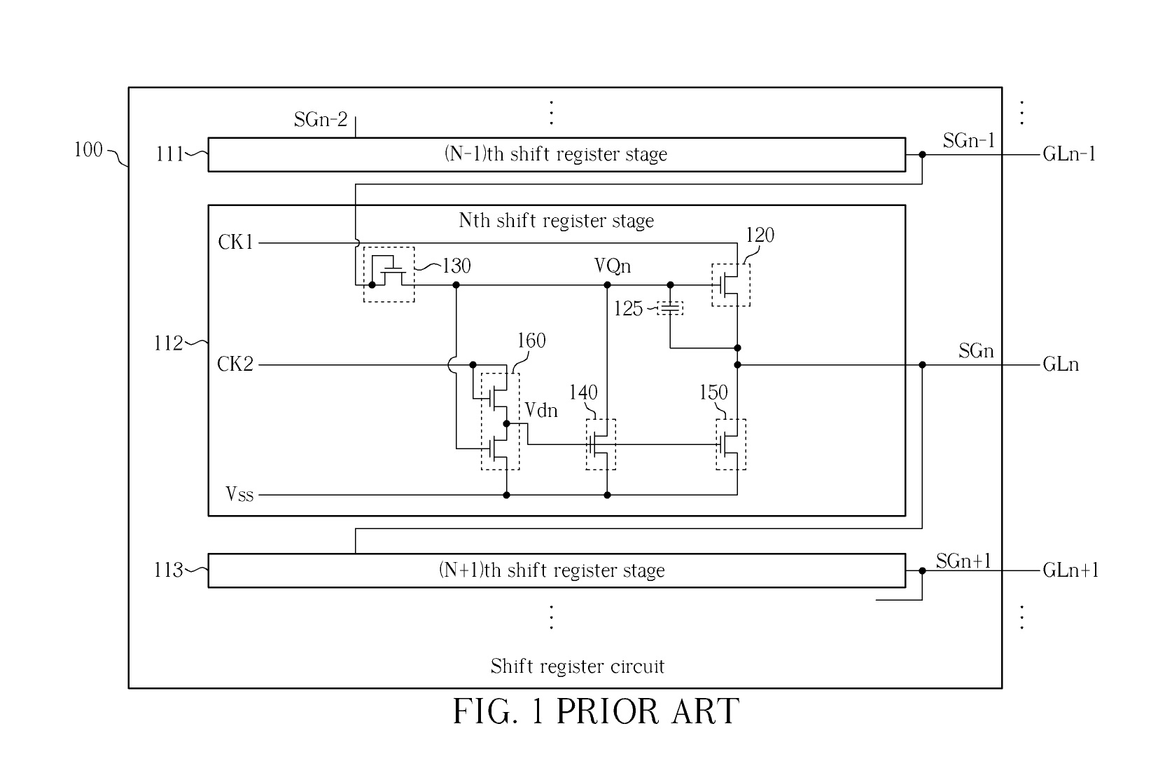

FIG. 2 is a schematic diagram showing related signal waveforms regarding the operation of the shift register circuit in FIG. 1, having time along the abscissa.

FIG. 3 is a schematic diagram showing a shift register circuit in accordance with a first embodiment of the present invention.

FIG. 4 is a schematic diagram showing related signal waveforms regarding the operation of the shift register circuit in FIG. 3, having time along the abscissa.

FIG. 5 is a schematic diagram showing a shift register circuit in accordance with a second embodiment of the present invention.

FIG. 6 is a schematic diagram showing a shift register circuit in accordance with a third embodiment of the present invention.

FIG. 7 is a schematic diagram showing related signal waveforms regarding the operation of the shift register circuit in FIG. 6, having time along the abscissa.

### DETAILED DESCRIPTION

Hereinafter, preferred embodiments of the present invention will be described in detail with reference to the accompanying drawings. Here, it is to be noted that the present invention is not limited thereto.

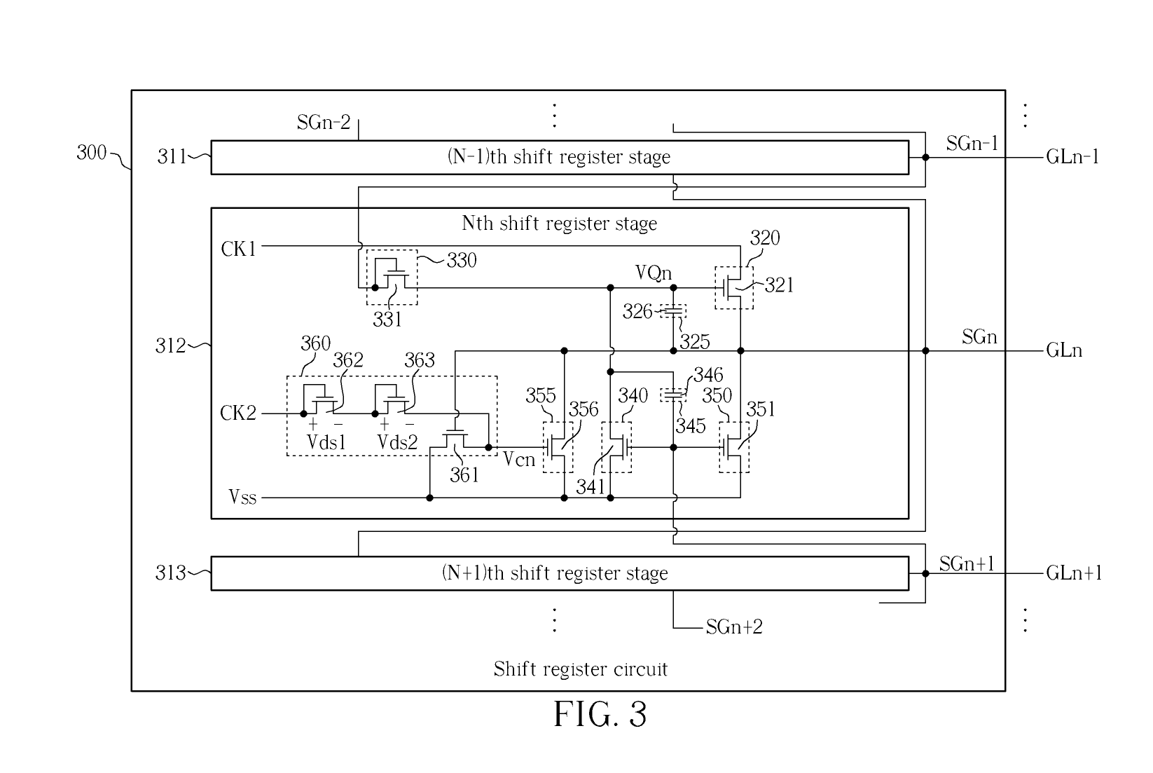

FIG. 3 is a schematic diagram showing a shift register circuit 300 in accordance with a first embodiment of the present invention. As shown in FIG. 3, the shift register circuit 300 comprises a plurality of shift register stages and, for ease of explanation, illustrates an (N−1)th shift register stage 311, an Nth shift register stage 312 and an (N+1)th shift register stage 313. For the sake of brevity, only the internal structure of the Nth shift register stage 312 is exemplified in detail. The other shift register stages are similar to the Nth shift register stage 312 and can be inferred by analogy. In the operation of the shift register circuit 300, the (N−1)th shift register stage 311 is employed to generate agate signal SGn−1 furnished to a gate line GLn−1, the Nth shift register stage 312 is employed to generate a gate signal SGn furnished to a gate line GLn, and the (N+1)th shift register stage 313 is employed to generate a gate signal SGn+1 furnished to a gate line GLn+1.

The Nth shift register stage 312 comprises a pull-up unit 320, an input unit 330, an energy-store unit 325, a discharging unit 340, a couple unit 345, a first pull-down unit 350, a second pull-down unit 355, and a control unit 360. The pull-up unit 320, electrically connected to the gate line GLn, is utilized for pulling up the gate signal SGn of the gate line GLn in response to a driving control voltage VQn and a first clock CK1. The input unit 330, electrically connected to the (N−1)th shift register stage 311, is utilized for inputting the gate signal SGn−1 to become the driving control voltage VQn. That is, the gate signal SGn−1 also functions as a start pulse signal for enabling the Nth shift register stage 312. The energy-store unit 325, electrically connected to the pull-up unit 320 and the input unit 330, is put in use for performing a charging process based on the gate signal SGn−1. The discharging unit 340, electrically connected to the energy-store unit 325 and the (N+1)th shift register stage 313, is employed to pull down the driving control voltage VQn through performing a discharging process in response to the gate signal SGn+1. The couple unit 345, electrically connected to the energy-store unit 325 and the (N+1)th shift register stage 313, is utilized for pulling down the driving control voltage VQn in response to the falling edge of the gate signal SGn+1. The first pull-down unit 350, electrically connected to the gate line GLn and the (N+1)th shift register stage 313, is utilized for pulling down the gate signal SGn in response to the gate signal SGn+1. The second pull-down unit 355, electrically connected to the gate line GLn, is utilized for pulling down the gate signal SGn in response to a pull-down control voltage Vcn. The control unit 360, electrically connected to the second pull-down unit 355 and the gate line GLn, is put in use for generating the pull-down control voltage Vcn in response to the gate signal SGn and a second clock CK2 having a phase opposite to the first clock CK1.

In the embodiment shown in FIG. 3, the pull-up unit 320 comprises a first transistor 321, the energy-store unit 325 comprises a first capacitor 326, the input unit 330 comprises a second transistor 331, the discharging unit 340 comprises a third transistor 341, the couple unit 345 comprises a second capacitor 346, the first pull-down unit 350 comprises a fourth transistor 351, the second pull-down unit 355 comprises a fifth transistor 356, and the control unit 360 comprises a sixth transistor 361, a seventh transistor 362 and an eighth transistor 363. The first transistor 321 through the eighth transistor 363 are thin film transistors, metal oxide semiconductor (MOS) field effect transistors, or junction field effect transistors.

The second transistor 331 comprises a first end electrically connected to the (N−1)th shift register stage 311 for receiving the gate signal SGn−1, a gate end electrically connected to the first end, and a second end electrically connected to the energy-store unit 325 and the pull-up unit 320. The first transistor 321 comprises a first end for receiving the first clock CK1, a gate end electrically connected to the second end of the second transistor 331, and a second end electrically connected to the gate line GLn. The first capacitor 326 is electrically connected between the gate and second ends of the first transistor 321. The third transistor 341 comprises a first end electrically connected to the second end of the second transistor 331, a gate end electrically connected the (N+1)th shift register stage 313 for receiving the gate signal SGn+1, and a second end for receiving a low power voltage Vss. The fourth transistor 351 comprises a first end electrically connected to the gate line GLn, a gate end electrically connected the (N+1)th shift register stage 313 for receiving the gate signal SGn+1, and a second end for receiving the low power voltage Vss. The second capacitor 346 is electrically connected between the first and gate ends of the third transistor 341. The fifth transistor 356 comprises a first end electrically connected to the gate line GLn, a gate end electrically connected to the control unit 360 for receiving the pull-down control voltage Vcn, and a second end for receiving the low power voltage Vss.

The sixth transistor 361 comprises a first end electrically connected to the gate end of the fifth transistor 356, a gate end electrically connected to the gate line GLn for receiving the gate signal SGn, and a second end for receiving the low power voltage Vss. The seventh transistor 362 comprises a first end for receiving the second clock CK2, a gate end electrically connected to the first end, and a second end. In another embodiment, the first end of the seventh transistor 362 is employed to receive a dc voltage capable of turning on both the seventh transistor 362 and the eighth transistor 363. The dc voltage may be the aforementioned high power voltage Vdd. The eighth transistor 363 comprises a first end electrically connected to the second end of the seventh transistor 362, a gate end electrically connected to the first end, and a second end electrically connected to the first end of the sixth transistor 361. The circuit functionalities of the second transistor 331, the seventh transistor 362 and the eighth transistor 363 are analogous to that of a diode, and the first and second ends thereof can be substantially construed as the anode and cathode of a diode.

As shown in FIG. 3, there is a first drain-source voltage drop Vds1 across the first and second ends of the seventh transistor 362. In addition, there is a second drain-source voltage drop Vds2 across the first and second ends of the eighth transistor 363. In one embodiment, the width/length ratio of the eighth transistor 363 is less than that of the sixth transistor 361 so as to provide greater second drain-source voltage drop Vds2 for significantly lowering the high voltage level of the pull-down control voltage Vcn. In another embodiment, both the width/length ratios of the seventh transistor 362 and the eighth transistor 363 are less than the width/length ratio of the sixth transistor 361 so as to provide greater first and second drain-source voltage drops Vds1, Vds2 for significantly lowering the high voltage level of the pull-down control voltage Vcn. In another embodiment, especially if the fifth transistor 356 is an MOS field effect transistor, the eighth transistor 363 is omitted, the second end of the seventh transistor 362 is connected directly to the first end of the sixth transistor 361, and the width/length ratio of the seventh transistor 362 is less than that of the sixth transistor 361 so as to provide greater first drain-source voltage drop Vds1 for significantly lowering the high voltage level of the pull-down control voltage Vcn.

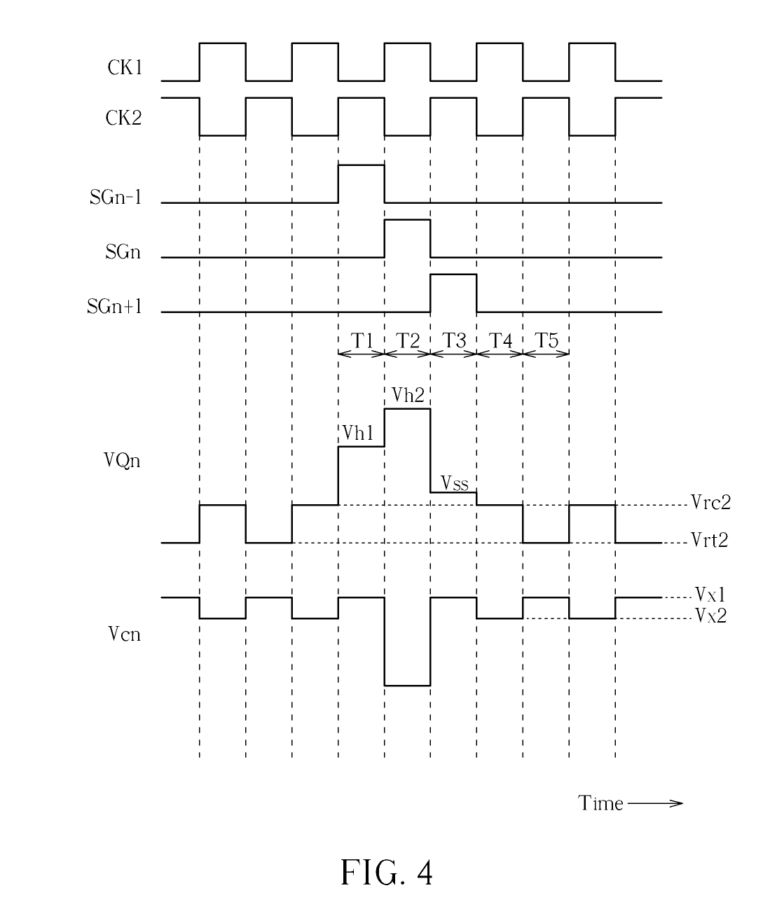

FIG. 4 is a schematic diagram showing related signal waveforms regarding the operation of the shift register circuit 300 in FIG. 3, having time along the abscissa. The signal waveforms in FIG. 4, from top to bottom, are the first clock CK1, the second clock CK2, the gate signal SGn−1, the gate signal SGn, the gate signal SGn+1, the driving control voltage VQn, and the pull-down control voltage Vcn.

As shown in FIG. 4, during an interval T1, the gate signal SGn−1 is shifting from low-level voltage to high-level voltage, the second transistor 331 is then turned on for boosting the driving control voltage VQn from low-level voltage to a first high voltage Vh1. During an interval T2, the gate signal SGn−1 is shifting from high-level voltage to low-level voltage, the second transistor 331 is then turned off and the driving control voltage VQn therefore becomes a floating voltage. Concurrently, along with the switching of the first clock CK1 from low-level voltage to high-level voltage, the driving control voltage VQn is further boosted from the first high voltage Vh1 to a second high voltage Vh2 due to a capacitive coupling effect caused by the device capacitor of the first transistor 321. Accordingly, the first transistor 321 is turned on for pulling up the gate signal SGn from low-level voltage to high-level voltage; meanwhile, the sixth transistor 361 is turned on by the gate signal SGn having high-level voltage for pulling down the pull-down control voltage Vcn to the low power voltage Vss so as to turn off the fifth transistor 356.

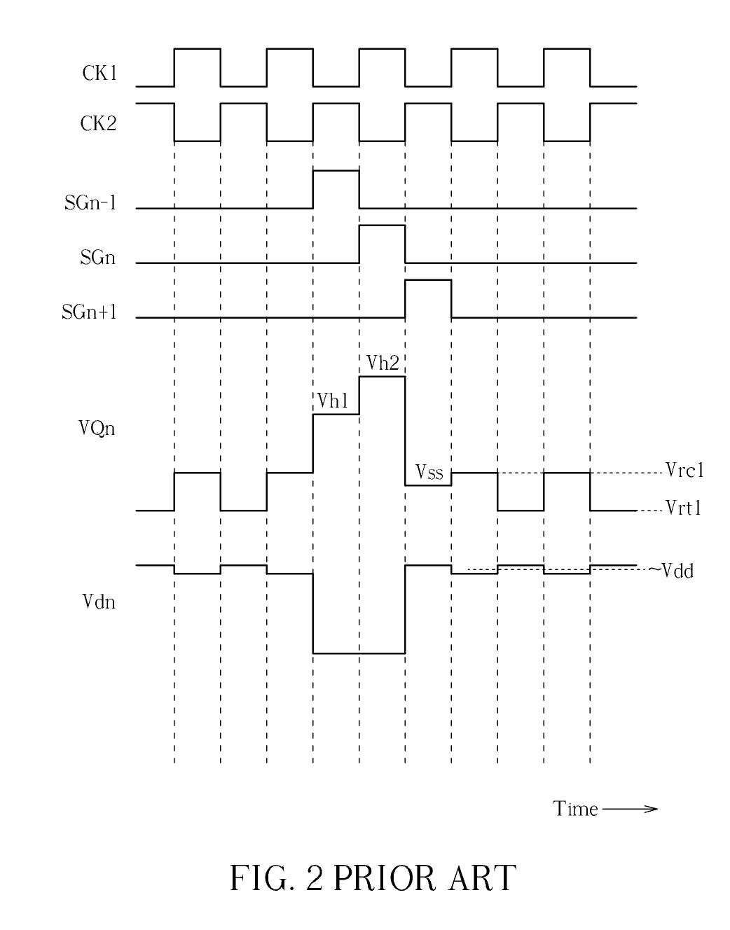

During an interval T3, the gate signal SGn is shifting down to low-level voltage following a decrease of the first clock CK1 from high-level voltage to low-level voltage, and the sixth transistor 361 is therefore turned off. In the meantime, the pull-down control voltage Vcn becomes a voltage Vx1 which is substantially lower than the high-level voltage of the second clock CK2 by a sum of the first and second drain-source voltage drops Vds1, Vds2. The fifth voltage 356 is then turned on by the voltage Vx1 for pulling down the gate signal SGn to the low power voltage Vss. Besides, by making use of the gate signal SGn as a start pulse signal, the (N+1) th shift register stage 313 is enabled to generate the gate signal SGn+1 having high-level voltage during the interval T3. In view of that, during the interval T3, the third transistor 341 and the fourth transistor 351 are turned on for pulling down the driving control voltage VQn and the gate signal SGn to the low power voltage Vss respectively. During an interval T4, the second clock CK2 is switching from high-level voltage to low-level voltage so that the seventh transistor 362 and the eighth transistor 363 are turned off. Concurrently, the pull-down control voltage Vcn is shifting down to a voltage Vx2 due to a capacitive coupling effect caused by the device capacitors of the seventh transistor 362 and the eighth transistor 363. The fifth transistor 356 is still turned on by the voltage Vx2 for pulling down the gate signal SGn to the low power voltage Vss. In the meanwhile, although the switching of the first clock CK1 from low-level voltage to high-level voltage is able to pull up the driving control voltage VQn due to the capacitive coupling effect caused by the device capacitor of the first transistor 321, the gate signal SGn+1 is switching from high-level voltage to low-level voltage and the falling edge of the gate signal SGn+1 is capable of pulling down the driving control voltage VQn via the coupling effect of the second capacitor 346. For that reason, the crest voltage Vrc2 regarding the ripple of the driving control voltage VQn is significantly lower than the crest voltage Vrc1, shown in FIG. 2, corresponding to the operation of the prior-art shift register circuit 100. During an interval T5, the second clock CK2 is switching from low-level voltage to high-level voltage so that the seventh transistor 362 and the eighth transistor 363 are turned on. Accordingly, the pull-down control voltage Vcn is pulled up to the voltage Vx1 again. Meanwhile, the first clock CK1 is switching from high-level voltage to low-level voltage. And the driving control voltage VQn is then pulled down from the crest voltage Vrc2 to a trough voltage Vrt2 due to the capacitive coupling effect caused by the device capacitor of the first transistor 321. It is obvious that the trough voltage Vrt2 is also significantly lower than the trough voltage Vrt1, shown in FIG. 2, corresponding to the operation of the prior-art shift register circuit 100.

Thereafter, as long as the gate signal SGn continues holding low-level voltage, the Nth shift register stage 312 periodically repeats the aforementioned circuit operations during the intervals T4 and T5. In view of that, the driving control voltage VQn is oscillating between the crest voltage Vrc2 and the trough voltage Vrt2, and the pull-down control voltage Vcn is oscillating between the voltage Vx1 and the voltage Vx2. In summary, by taking advantage of the coupling effect of the second capacitor 346, the crest voltage Vrc2 regarding the ripple of the driving control voltage VQn can be significantly lower than zero voltage for reducing the leakage current of the first transistor 321. That is, significantly voltage drift event will not occur to the voltage level of the gate signal SGn so as to ensure high display quality, and the power consumption in the operation of the shift register circuit 300 can be reduced. Besides, due to the drain-source voltage drops of the seventh and eighth transistor 362, 363, the high voltage level of the pull-down control voltage Vcn can be lowered significantly to mitigate the voltage stress of the fifth transistor 356 for preventing an occurrence of threshold voltage shift and enhancing the reliability and life-time of the shift register circuit 300.

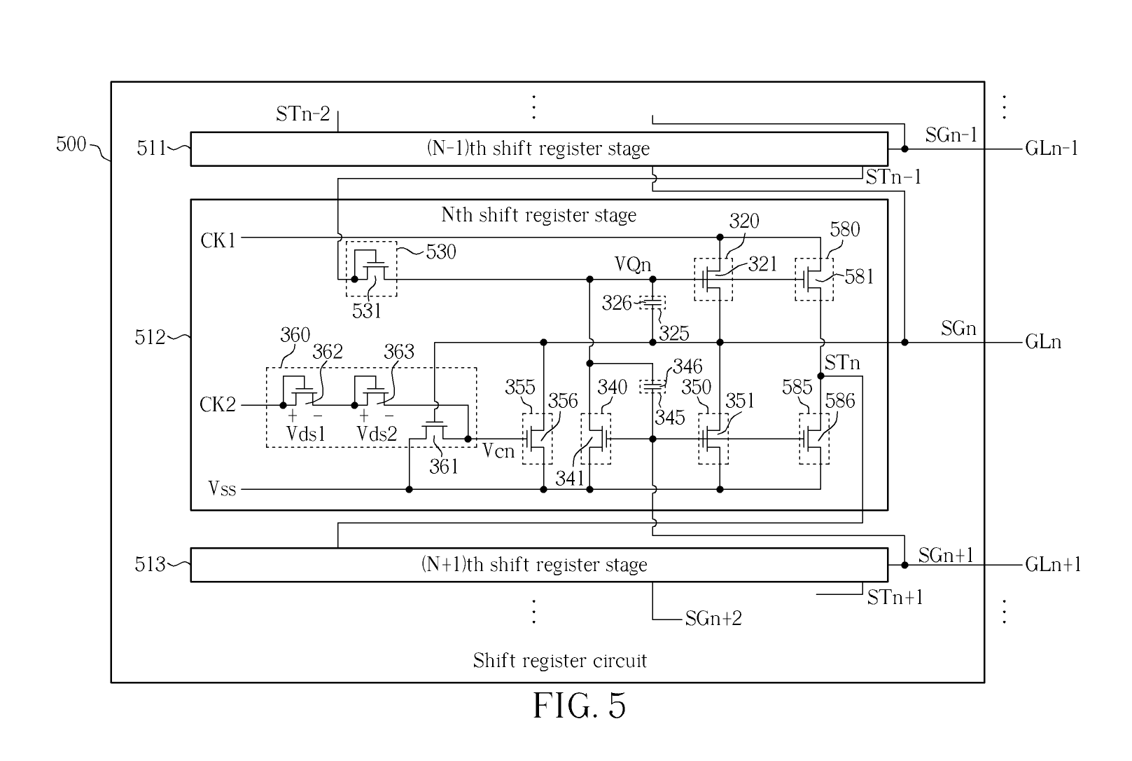

FIG. 5 is a schematic diagram showing a shift register circuit 500 in accordance with a second embodiment of the present invention. As shown in FIG. 5, the shift register circuit 500 comprises a plurality of shift register stages and, for ease of explanation, illustrates an (N−1)th shift register stage 511, an Nth shift register stage 512 and an (N+1)th shift register stage 513. For the sake of brevity, only the internal structure of the Nth shift register stage 512 is exemplified in detail. The other shift register stages are similar to the Nth shift register stage 512 and can be inferred by analogy. Compared with the shift register circuit 300 shown in FIG. 3, the (N−1)th shift register stage 511 is further employed to provide a start pulse signal STn−1, the Nth shift register stage 512 is further employed to provide a start pulse signal STn, and the (N+1)th shift register stage 513 is further employed to provide a start pulse signal STn+1. In the operation of the shift register circuit 500, the waveform of the start pulse signal STn−1 is substantially identical to that of the gate signal SGn−1, the waveform of the start pulse signal STn is substantially identical to that of the gate signal SGn, and the waveform of the start pulse signal STn+1 is substantially identical to that of the gate signal SGn+1.

The circuit structure of the Nth shift register stage 512 is similar to that of the Nth shift register stage 312 shown in FIG. 3, differing in that a carry unit 580 and a third pull-down unit 585 are further added and the input unit 330 is replaced with an input unit 530. The carry unit 580, electrically connected to the (N+1)th shift register stage 513, is utilized for generating the start pulse signal STn, furnished to the (N+1)th shift register stage 513, in response to the driving control voltage VQn and the first clock CK1. The third pull-down unit 585, electrically connected to the carry unit 580 and the (N+1)th shift register stage 513, is utilized for pulling down the start pulse signal STn in response to the gate signal SGn+1. The input unit 530, electrically connected to the (N−1)th shift register stage 511, is utilized for inputting the start pulse signal STn−1 to become the driving control voltage VQn.

In the embodiment shown in FIG. 5, the input unit 530 comprises a second transistor 531, the carry unit 580 comprises a ninth transistor 581, and the third pull-down unit 585 comprises a tenth transistor 586. The second transistor 531, the ninth transistor 581 and the tenth transistor 586 are thin film transistors, MOS field effect transistors, or junction field effect transistors. The second transistor 531 comprises a first end electrically connected to the carry unit of the (N−1)th shift register stage 511 for receiving the start pulse signal STn−1, a gate end electrically connected to the first end, and a second end electrically connected to the energy-store unit 325, the pull-up unit 320 and the carry unit 580. The ninth transistor 581 comprises a first end for receiving the first clock CK1, a gate end electrically connected the second end of the second transistor 531, and a second end electrically connected to the input unit of the (N+1)th shift register stage 513. The tenth transistor 586 comprises a first end electrically connected to the second end of the ninth transistor 581, a gate end electrically connected to the (N+1)th shift register stage 513 for receiving the gate signal SGn+1, and a second end for receiving the low power voltage Vss. The signal waveforms regarding the operation of the shift register circuit 500 are substantially identical to the signal waveforms shown in FIG. 4 and, for the sake of brevity, further similar discussion thereof is omitted.

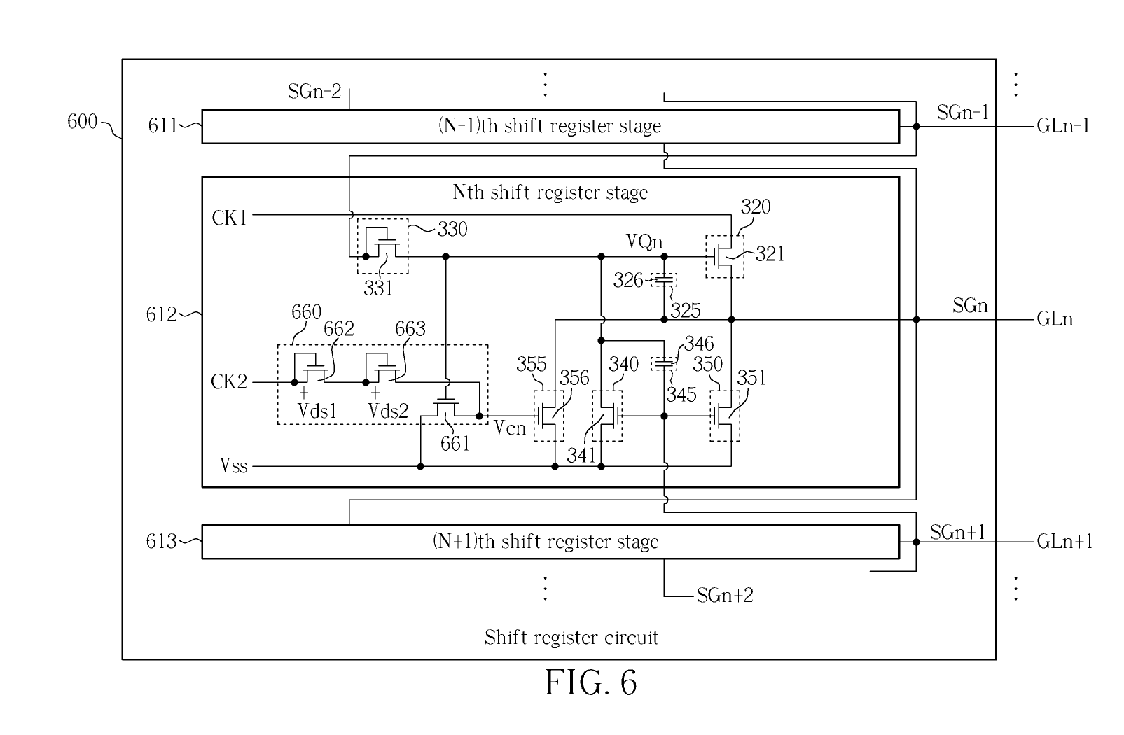

FIG. 6 is a schematic diagram showing a shift register circuit 600 in accordance with a third embodiment of the present invention. As shown in FIG. 6, the shift register circuit 600 comprises a plurality of shift register stages and, for ease of explanation, illustrates an (N−1)th shift register stage 611, an Nth shift register stage 612 and an (N+1)th shift register stage 613. For the sake of brevity, only the internal structure of the Nth shift register stage 612 is exemplified in detail. The other shift register stages are similar to the Nth shift register stage 612 and can be inferred by analogy. The circuit structure of the Nth shift register stage 612 is similar to that of the Nth shift register stage 312 shown in FIG. 3, differing in that the control unit 360 is replaced with a control unit 660. The control unit 660, electrically connected to the second pull-down unit 355 and the energy-store unit 325, is utilized for generating the pull-down control voltage Vcn in response to the second clock CK2 and the driving control voltage VQn.

In the embodiment shown in FIG. 6, the control unit 660 comprises a sixth transistor 661, a seventh transistor 662 and an eighth transistor 663. The sixth transistor 661 comprises a first end electrically connected to the gate end of the fifth transistor 356, a gate end electrically connected to the energy-store unit 325 for receiving the driving control voltage VQn, and a second end for receiving the low power voltage Vss. The seventh transistor 662 comprises a first end for receiving the second clock CK2, a gate end electrically connected to the first end, and a second end. In another embodiment, the first end of the seventh transistor 662 is employed to receive a dc voltage capable of turning on both the seventh transistor 662 and the eighth transistor 663. The dc voltage may be the aforementioned high power voltage Vdd. The eighth transistor 663 comprises a first end electrically connected to the second end of the seventh transistor 662, a gate end electrically connected to the first end, and a second end electrically connected to the first end of the sixth transistor 661. The sixth transistor 661, the seventh transistor 662 and the eighth transistor 663 are thin film transistors, MOS field effect transistors, or junction field effect transistors.

In one embodiment, the width/length ratio of the eighth transistor 663 is less than that of the sixth transistor 661 so as to provide greater second drain-source voltage drop Vds2 for significantly lowering the high voltage level of the pull-down control voltage Vcn. In another embodiment, both the width/length ratios of the seventh transistor 662 and the eighth transistor 663 are less than the width/length ratio of the sixth transistor 661 so as to provide greater first and second drain-source voltage drops Vds1, Vds2 for significantly lowering the high voltage level of the pull-down control voltage Vcn. In another embodiment, especially if the fifth transistor 356 is an MOS field effect transistor, the eighth transistor 663 is omitted, the second end of the seventh transistor 662 is connected directly to the first end of the sixth transistor 661, and the width/length ratio of the seventh transistor 662 is less than that of the sixth transistor 661 so as to provide greater first drain-source voltage drop Vds1 for significantly lowering the high voltage level of the pull-down control voltage Vcn.

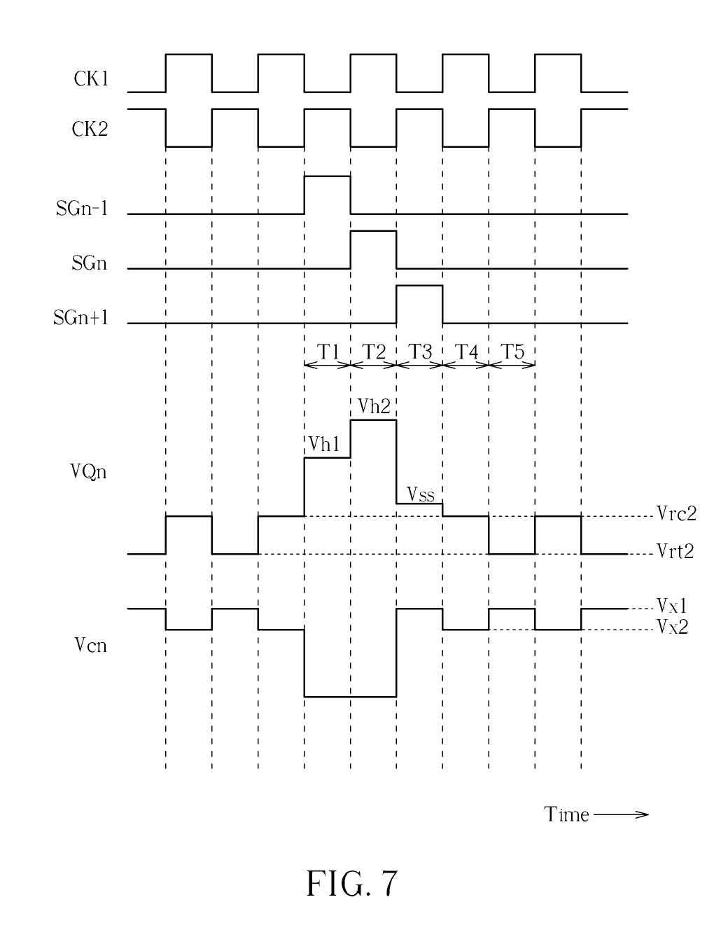

FIG. 7 is a schematic diagram showing related signal waveforms regarding the operation of the shift register circuit 600 in FIG. 6, having time along the abscissa. The signal waveforms in FIG. 7, from top to bottom, are the first clock CK1, the second clock CK2, the gate signal SGn−1, the gate signal SGn, the gate signal SGn+1, the driving control voltage VQn, and the pull-down control voltage Vcn. The signal waveforms shown in FIG. 7 are similar to the signal waveforms shown in FIG. 4, differing in that the pull-down control voltage Vcn is pulled down to low-level voltage during the interval T1, which results from the fact that the gate end of the sixth transistor 661 is for receiving the driving control voltage VQn instead of the gate signal SGn. And as aforementioned, the driving control voltage VQn is the first high voltage Vh1 during the interval T1 so that the sixth transistor 661 is also turned on during the interval T1 as well as during the interval T2. For that reason, the pull-down control voltage Vcn is pulled down to the low power voltage Vss during both the intervals T1 and T2. Except for the signal waveform of the pull-down control voltage Vcn during the interval T1, the other signal waveforms in FIG. 7 are substantially identical to the signal waveforms in FIG. 4 and, for the sake of brevity, further similar discussion is omitted.

In conclusion, the shift register circuit of the present invention employs the couple unit to significantly lower the crest voltage regarding the ripple of the driving control voltage for reducing the leakage current of the transistor driven by the driving control voltage so that the gate signals generated will not drift significantly for ensuring high display quality and the power consumption in the operation of the shift register circuit can be reduced. Further, due to the drain-source voltage drop of at least one transistor in the control unit, the high voltage level of the pull-down control voltage can be lowered significantly to mitigate the voltage stress of the transistor controlled by the pull-down control voltage, for preventing an occurrence of threshold voltage shift and enhancing the reliability and life-time of the shift register circuit.

The present invention is by no means limited to the embodiments as described above by referring to the accompanying drawings, which may be modified and altered in a variety of different ways without departing from the scope of the present invention. Thus, it should be understood by those skilled in the art that various modifications, combinations, sub-combinations and alternations might occur depending on design requirements and other factors insofar as they are within the scope of the appended claims or the equivalents thereof.

What is claimed is:

1. A shift register circuit for providing plural gate signals to plural gate lines, the shift register circuit comprising a plurality of shift register stages, an Nth shift register stage of the shift register stages comprising:
a pull-up unit, electrically connected to an Nth gate line of the gate lines, for pulling up an Nth gate signal of the gate signals in response to a driving control voltage and a first clock;
an input unit, electrically connected to the pull-up unit and an (N−1)th shift register stage of the shift register stages, for inputting a first input signal to become the driving control voltage;
an energy-store unit, electrically connected to the pull-up unit and the input unit, for performing a charging process based on the first input signal;
a discharging unit, electrically connected to the energy-store unit and an (N+1)th shift register stage of the shift register stages, for pulling down the driving control voltage through performing a discharging process in response to an (N+1)th gate signal of the gate signals;
a couple unit, electrically connected to the energy-store unit and the (N+1)th shift register stage, for pulling down the driving control voltage in response to a falling edge of the (N+1)th gate signal;
a first pull-down unit, electrically connected to the Nth gate line and the (N+1)th shift register stage, for pulling down the Nth gate signal in response to the (N+1)th gate signal;
a second pull-down unit, electrically connected to the Nth gate line, for pulling down the Nth gate signal in response to a pull-down control voltage; and
a control unit, electrically connected to the second pull-down unit, for generating the pull-down control voltage in response to a second input signal.

2. The shift register circuit of claim 1, wherein the energy-store unit comprises a capacitor.

3. The shift register circuit of claim 1, wherein the couple unit comprises a capacitor.

4. The shift register circuit of claim 1, wherein the pull-up unit comprises a transistor, the transistor comprising:
a first end for receiving the first clock;
a gate end, electrically connected to the input unit, for receiving the driving control voltage; and
a second end electrically connected to the Nth gate line.

5. The shift register circuit of claim 1, wherein the input unit comprises a transistor, the transistor comprising:
a first end, electrically connected to the (N−1)th shift register stage, for receiving the first input signal;
a gate end electrically connected to the first end; and
a second end electrically connected to the energy-store unit and the pull-up unit;
wherein the first input signal is an (N−1)th gate signal.

6. The shift register circuit of claim 1, wherein the discharging unit comprises a transistor, the transistor comprising:
a first end electrically connected to the energy-store unit;
a gate end, electrically connected to the (N+1)th shift register stage, for receiving the (N+1)th gate signal; and
a second end for receiving a low power voltage.

7. The shift register circuit of claim 1, wherein the first pull-down unit comprises a transistor, the transistor comprising:
a first end electrically connected to the Nth gate line;
a gate end, electrically connected to the (N+1)th shift register stage, for receiving the (N+1)th gate signal; and
a second end for receiving a low power voltage.

8. The shift register circuit of claim 1, wherein the second pull-down unit comprises a transistor, the transistor comprising:
a first end electrically connected to the Nth gate line;
a gate end, electrically connected to the control unit, for receiving the pull-down control voltage; and
a second end for receiving a low power voltage.

9. The shift register circuit of claim 1, wherein the control unit comprises:
a first transistor comprising:
a first end, electrically connected to the second pull-down unit, for outputting the pull-down control voltage;
a gate end, electrically connected to the Nth gate line for receiving the Nth gate signal, or electrically connected to the input unit for receiving the driving control voltage; and
a second end for receiving a low power voltage; and
a second transistor comprising:
a first end for receiving the second input signal;
a gate end electrically connected to the first end of the second transistor; and
a second end electrically connected to the first end of the first transistor.

10. The shift register circuit of claim 9, wherein the second input signal is a dc voltage or a second clock having a phase opposite to the first clock.

11. The shift register circuit of claim 9, wherein the first transistor and the second transistor are thin film transistors or field effect transistors.

12. The shift register circuit of claim 11, wherein a width/length ratio of the second transistor is less than a width/length ratio of the first transistor.

13. The shift register circuit of claim 9, wherein the control unit further comprises a third transistor, the third transistor comprising:
a first end electrically connected to the second end of the second transistor;
a gate end electrically connected to the first end of the third transistor; and
a second end electrically connected to the first end of the first transistor.

14. The shift register circuit of claim 13, wherein the first transistor, the second transistor and the third transistor are thin film transistors or field effect transistors.

15. The shift register circuit of claim 14, wherein a width/length ratio of the third transistor is less than a width/length ratio of the first transistor.

16. The shift register circuit of claim 15, wherein a width/length ratio of the second transistor is less than the width/length ratio of the first transistor.

17. The shift register circuit of claim 1, wherein the Nth shift register stage further comprises:
a carry unit, electrically connected to the input unit and the energy-store unit, for pulling up an Nth start pulse signal in response to the driving control voltage and the first clock, the Nth start pulse signal being forwarded to an input unit of the (N+1)th shift register stage; and
a third pull-down unit, electrically connected to the carry unit and the (N+1)th shift register stage, for pulling down the Nth start pulse signal in response to the (N+1)th gate signal.

18. The shift register circuit of claim 17, wherein the input unit of the Nth shift register stage comprises a transistor, the transistor comprising:
a first end, electrically connected to the (N−1)th shift register stage, for receiving an (N−1)th start pulse signal;
a gate end electrically connected to the first end; and
a second end electrically connected to the energy-store unit, the pull-up unit and the carry unit;
wherein the first input signal is the (N−1)th start pulse signal.

19. The shift register circuit of claim 17, wherein the carry unit of the Nth shift register stage comprises a transistor, the transistor comprising:
a first end for receiving the first clock;
a gate end, electrically connected to the input unit of the Nth shift register stage, for receiving the driving control voltage; and
a second end electrically connected to the input unit of the (N+1)th shift register stage.

20. The shift register circuit of claim 17, wherein the third pull-down unit of the Nth shift register stage comprises a transistor, the transistor comprising:
a first end electrically connected to the carry unit;
a gate end electrically connected to the (N+1)th shift register stage for receiving the (N+1)th gate signal; and
a second end for receiving a low power voltage.
